(19) United States
(12) Patent Application Publication
(10) Pub. No.: US 2006/0170510 A1
(43) Pub. Date: Aug. 3, 2006

(54) MOUNTING STRUCTURE AND METHOD OF SURFACE-MOUNT CRYSTAL OSCILLATOR

(76) Inventor: Kouichi MORIYA, Sayama-shi, Saitama (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/380,585

(22) Filed: Apr. 27, 2006

(30) Foreign Application Priority Data
Apr. 28, 2005 (JP) 2005-133487

(51) Int. Cl. H03B 5/32

(52) U.S. Cl. 331/158

(57) ABSTRACT

A surface-mount crystal oscillator including a container body, a mounting terminal arranged on an outer bottom surface of the container body, a crystal blank hermetically sealed in said container body, and an IC chip having an oscillation circuit electrically connected to the crystal blank and hermetically sealed in the container body is mounted on a circuit board. A discrete part is arranged on the outer bottom surface of the container body, and the circuit board is provided with a connection terminal corresponding to the mounting terminal and an opening corresponding to the discrete part. The mounting terminal and the connection terminal are electrically and mechanically connected in a manner that the discrete part is accommodated in the opening, whereby the surface-mount crystal oscillator is surface-mounted on the circuit board.

### BACKGROUND OF THE INVENTION

1. Field of the Invention

The present invention relates to a structure and a method of mounting a surface-mount quartz crystal oscillator on a circuit board or wiring board, and in particularly, relates to a structure and a method of mounting a miniaturized surface-mount temperature-compensated crystal oscillator on a circuit board in a portable device.

2. Description of the Related Art

A surface-mount crystal oscillator in which a crystal unit and an oscillation circuit using this crystal unit are accommodated in a container for surface-mounting is widely installed in various devices as a reference source of frequency or time, because it is compact and lightweight. Out of surface-mount crystal oscillators like this, a surface-mount temperature-compensated crystal oscillator provided with a temperature compensating mechanism for compensating for the change in the oscillation frequency caused by the frequency vs. temperature characteristics of the quartz crystal unit can provide improved frequency stability relative to the temperature and can maintain the oscillation frequency stable regardless of the change in the ambient temperature. Therefore, the surface-mount temperature-compensated crystal oscillator is widely used as the reference source of frequency in a mobile telephone, cellular phone or the like that is used in mobile environment. Recently, as various potable devices represented by a mobile telephone have been rapidly reduced in size, there has been a demand for further size reduction in surface-mount crystal oscillators, in particular, surface-mount temperature-compensated crystal oscillators.

Hereinafter, the temperature-compensated crystal oscillator is explained. The assignee of the present invention has already proposed temperature-compensated crystal oscillators with reduced phase noise in Japanese Patent Laid-Open Applications Nos. 2001-196356 and 2001-44758 (JP, 2001-196356A and JP, 2001-044758A).

FIG. 1 shows a circuit configuration of a conventional temperature-compensated crystal oscillator, and FIGS. 2A to 2C are a cross-sectional view, a plan view, and a rear view of the surface-mount temperature-compensated crystal oscillator, respectively. Note that FIG. 2A is a plan view of the surface-mount temperature-compensated crystal oscillator in a state that a cover is removed.

The temperature-compensated crystal oscillator is provided with temperature compensating mechanism 2 in addition to crystal oscillator 1. Crystal oscillator 1 is provided with quartz crystal unit 3 and oscillation circuit 4 electrically connected to crystal unit 3, and is further provided with voltage-variable capacitive element 5, such as a variable capacitance diode, in the oscillation closed loop of the crystal oscillator. Temperature compensating mechanism 2 is provided with compensating voltage generation circuit 6 and low-pass filter 7. Compensating voltage generation circuit 6 detects the ambient temperature and generates a compensating voltage in response to the ambient temperature. Low-pass filter 7 comprises resistor R and capacitor C, and is connected to compensating voltage generation circuit 6 to apply the compensating voltage to voltage-variable capacitive element 5 through high frequency blocking resistor 9. Low-pass filter 7 suppresses the high frequency component (i.e., ac component) that is a noise component in the compensating voltage, and reduces phase noise in the output signal from the temperature-compensated crystal oscillator without applying the noise component to voltage-variable capacitive element 5.

Switching element 8 is provided in parallel to resistor R in low-pass filter 7. Switching element 8 becomes a conductive state when the temperature-compensated crystal oscillator starts up and becomes an interruption state immediately after that, and is provided to prevent the oscillation frequency from being unstable due to the time constant of low-pass filter 7 when the temperature-compensated crystal oscillator starts up.

In such a temperature-compensated crystal oscillator, temperature compensating mechanism 2 except capacitor C in low-pass filter 7 and oscillation circuit 4 including voltage-variable capacitive element 5 are integrated in IC (integrated circuit) chip 11, as shown in FIG. 2A. The value of resistor R in low-pass filter 7 is, for example, 2 MΩ, and the value of capacitor C is about 10000 pF based on the time constant required by low-pass filter 7. Since IC chip 11 is generally formed by using the silicon semiconductor device fabrication technology, the capacitance value of capacitor C is large and thus it is difficult to integrate capacitor C in IC chip 11. Therefore, capacitor C is provided in the temperature-compensated crystal oscillator as a discrete part.

So, the conventional surface-mount temperature-compensated crystal oscillator uses container body 10 for surface-mounting in an approximate rectangular parallelepiped shape with a recess and is configured by integrally accommodating IC chip 11, chip capacitor C′ as capacitor C of low-pass filter 7, and quartz crystal blank 12 as a crystal unit in the recess, as shown in FIGS. 2A to 2C. Cover 13 made of metal is put over an opening of the recess, and thus IC chip 11, chip capacitor C′, and crystal blanks 12 are hermetically sealed in container body 10. Container body 10 is formed by laminated ceramics or the like, and a step portion is formed on the inner wall of container body 10. IC chip 11 is fixed to the inner bottom surface of the recess by ultrasonic thermo-compression using a bump (not shown). Chip capacitor C′ is fixed to the bottom surface of the recess in a concave portion formed on the inner wall of the recess by solder or the like. Crystal blank 12 is, for example, AT-cut quartz crystal blank in a rectangular shape and is provided with excitation electrodes (not shown) on both main surfaces thereof. A pair of extending electrodes extends toward both sides of one end portion of the crystal blank from the excitation electrodes. The both sides of one end portion of crystal blank 12, where the extending electrodes extend, are fixed to the step portion in the recess by conductive adhesive 14, whereby crystal blank 12 is horizontally held in the recess over IC chip 11.

At four corners of the outer bottom surface of container body 10, four mounting terminals 15, i.e., output terminal (OUT) for outputting an oscillation signal, power source terminal (Vcc), input terminal (AFC) to which an automatic frequency control signal is applied, and ground terminal (GND), are respectively arranged. Such mounting terminal 15 is electrically connected to each terminal (not shown) of IC chip 11 by an end face electrode, such as a through-hole, formed on the side surface of container body 10. Crystal blank 12 is also electrically connected to terminals for crystal unit connection of IC chip 11 by conductive adhesive 14 and circuit patterns (not shown) formed on the surface of the recess of container body 10. Mounting terminals 15 are used when the surface-mount temperature-compensated crystal oscillator is installed on the circuit board for the device that uses the surface-mount temperature-compensated crystal oscillator. Mounting terminals 15 are connected to circuit patterns on the circuit board by solder or the like, and thus the surface-mount temperature-compensated crystal oscillator is surface-mounted on the circuit board. On the circuit board, another circuit element or circuit block (not shown) of the device that uses the surface-mount temperature-compensated crystal oscillator is also mounted.

In the above-mentioned surface-mount temperature-compensated crystal oscillator, the size reduction is advanced, and the planar outer size is, for example, about 2.5×2.0 mm. Accordingly, the area of the bottom in the recess of container body 10 is small, the thickness of the frame wall portion of that surrounds the recess in container body 10 is thin, and thus it becomes difficult to provide a concave portion in the inner wall of the recess. Therefore, chip capacitor C′, which is a discrete part of low-pass filter 7, cannot be accommodated in the recess.

Also, as shown in FIG. 3, in low-pass filter 7, cut-off frequency fα where the high frequency component starts to attenuate is determined by the time constant specified by capacitor C and resistor R. In the case of the above-mentioned temperature-compensated crystal oscillator, since resistor R is integrated with IC chip 11 and capacitor C is hermetically sealed in the recess as chip capacitor C′, there is a problem in that the time constant cannot be changed and adjusted after the temperature-compensated oscillator is assembled.

When cut-off frequency fα is set low to minimize the high frequency component (i.e., ac component) that is a noise component, the time constant of low-pass filter 7 may be set large. However, in this case, when the temperature-compensated voltage is changed in response to the temperature, it take much time until the potential at the junction between resistor R and capacitor C in low-pass filter is stabilized, and the tractability of temperature compensation becomes worse. For this reason, for example, when the temperature changes rapidly, the temperature is not compensated sufficiently and there is a possibility in that the oscillation frequency fluctuates. To the contrary, when the tractability is made better by making the time constant small, cut-off frequency fα becomes high and the noise component included in the compensating voltage increases, and thus the phase noise characteristic of the temperature-compensated oscillator becomes worse. For these reasons, in the temperature-compensated crystal oscillator, preferably, the time constant of the low-pass filter is changed in accordance with uses. For example, when the temperature-compensated crystal oscillator is arranged in a device that will be principally used in a room environment with little variations in temperature, the time constant is made large and the noise component included in the compensating voltage is made small. Also, when the temperature-compensated crystal oscillator is arranged in a device that will be used outdoors with large variations in temperature, the time constant is made small and the tractability of the temperature compensation is ensured.

In order to make the time constant larger, the resistance of resistor R and capacitance of capacitor C may be made larger. However, since resistor R is integrated in IC chip 11, there are limitations on increasing the value of the resistance and the value cannot be changed after the temperature-compensated crystal oscillator is assembled. Therefore, in order to make the time constant larger, external chip capacitor C′ may be made larger while the value of resistor R is constant. However, when the capacitance is made larger, the outer dimensions of chip capacitor C′ are large, and there is a case where chip capacitor C′ cannot be accommodated in container body 10. In this regard, in low-pass filter 7, cut-off frequency fα is 8 Hz when resistor R is set to 2 MΩ and capacitor C is set to 10000 pF. With this arrangement, the attenuation amount relative to the high frequency component of the megahertz band becomes large and the noise component is reduced. The lower cut-off frequency fα is, the larger the attenuation of the high frequency component is.

Further, it is useful that the time constant can be changed freely in accordance with use environment after the temperature-compensated crystal oscillator is assembled. However, according the configuration in which both resistor R and capacitor C making up low-pass filter 7 are accommodated in the recess of container body 10, the time constant cannot be adjusted after the temperature-compensated crystal oscillator is assembled.

### SUMMARY OF THE INVENTION

It is an object of the present invention to provide a structure and a method of mounting a surface-mount crystal oscillator that maintains miniaturization while being provided with discrete parts, such as a large-capacitance chip capacitor, on a circuit board.

It is another object of the present invention to provide a structure and a method of mounting a surface-mount crystal oscillator in which the time constant of the low-pass filter can be changed after the temperature-compensated crystal oscillator is assembled while the miniaturization of the surface-mount temperature-compensated crystal oscillator having a low-pass filter in a temperature compensating mechanism is promoted.

The mounting structure of the present invention is a structure in which a surface-mount crystal oscillator comprising a container body, a mounting terminal arranged on an outer bottom surface of the container body, a crystal blank hermetically sealed in the container body, and an IC chip having an oscillation circuit electrically connected to the crystal blank and hermetically sealed in the container body is mounted on a circuit board: wherein a discrete part electrically connected to the IC chip is arranged on the outer bottom surface of the container body, the circuit board is provided with a connection terminal corresponding to the mounting terminal and an opening corresponding to the discrete part, the mounting terminal and the connection terminal are electrically and mechanically connected in a manner that said discrete part is accommodated in said opening, whereby said surface-mount crystal oscillator is surface-mounted on said circuit board.

The mounting method of the present invention is a method of mounting a surface-mount crystal oscillator on a circuit board, the surface-mount crystal oscillator comprising a container body, a mounting terminal arranged on an outer bottom surface of the container body, a crystal blank hermetically sealed in the container body, and an IC chip having an oscillation circuit electrically connected to the crystal blank and hermetically sealed in the container body, the method comprising the steps of:

preparing the surface-mount crystal oscillator in which a discrete part electrically connected to the IC chip is arranged on the outer bottom surface of the container body; and

electrically and mechanically connecting the mounting terminal and a connection terminal, which is provided on the circuit board, in a manner that the discrete part is accommodated in an opening provided in the circuit board, whereby the surface-mount crystal oscillator is surface-mounted on the circuit board.

In the present invention, the discreet part is, for example, a chip capacitor. Preferably, the surface-mount crystal oscillator is a surface-mount temperature-compensated crystal oscillator including a temperature compensating mechanism for performing temperature compensation of an oscillation frequency of the surface-mount crystal oscillator, and the discrete part is a capacitor in a low-pass filter included in the temperature compensating mechanism in this case. In the present invention, the circuit board includes a wiring board and the like.

According to the present invention, since the discrete part such as a chip capacitor is accommodated in the opening provided in the circuit board, the height of the crystal oscillator from the circuit board surface can be reduced and the substantial height of the crystal oscillator can be reduced. Therefore according to the present invention, the surface-mount crystal oscillator can be reduced in size wile being equipped with the large-capacitance chip capacitor.

Also, according to the present invention, when the discrete part is the capacitor of the low-pass filter in the temperature-compensated crystal oscillator, the time constant of the low-pass filter can be changed freely in response to the use environment or the like after the temperature-compensated crystal oscillator.

### BRIEF DESCRIPTION OF THE DRAWINGS

FIG. 1 is a schematic circuit diagram showing a surface-mount temperature-compensated crystal oscillator;

FIGS. 2A to 2C are respectively a cross-sectional view, a plan view, and a rear view showing a conventional surface-mount temperature-compensated crystal oscillator;

FIG. 3 is a schematic graph showing a frequency attenuation characteristic of a low-pass filter used in a temperature-compensated crystal oscillator;

FIG. 4A is a cross-sectional view for explaining a mounting structure of a surface-mount temperature-compensated crystal oscillator according to an embodiment of the present invention;

FIG. 4B is a rear view of the surface-mount temperature-compensated crystal oscillator according to the present invention; and

FIG. 5 is a circuit diagram of another surface-mount temperature-compensated crystal oscillator to which the mounting structure of the present invention is applied.

### DETAILED DESCRIPTION OF THE PREFERRED EMBODIMENTS

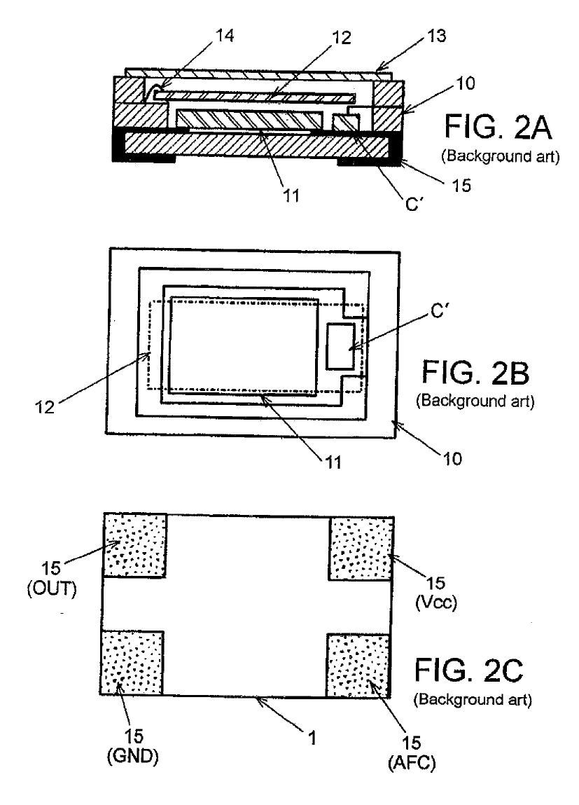

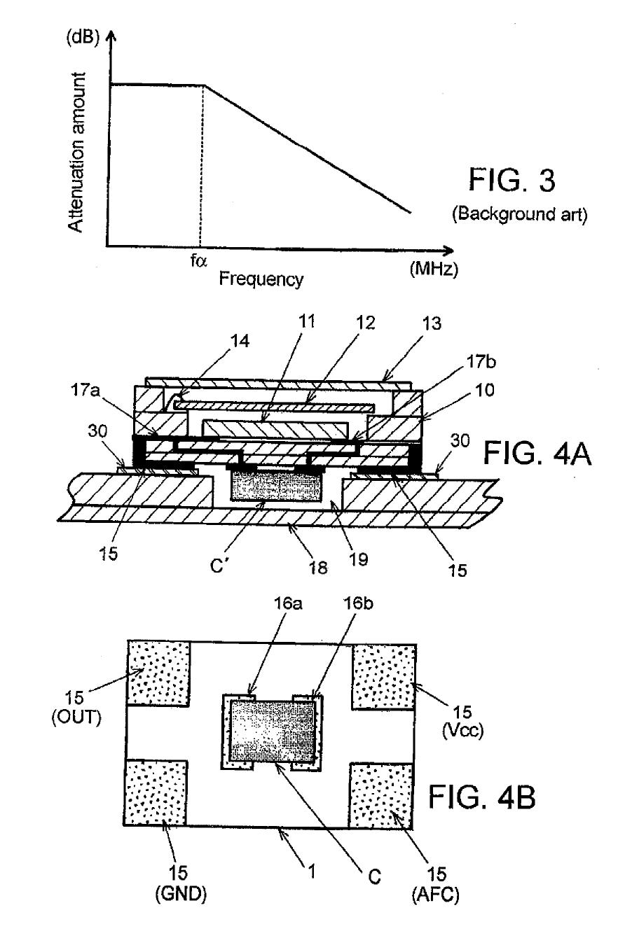

Explanations are given of mounting a surface-mount crystal oscillator on a circuit board or wiring board according to the method of the present invention with reference to a case in that a surface-mount temperature-compensated crystal oscillator is mounted on a circuit board. FIG. 4A shows the mounting structure of the surface-mount temperature-compensated crystal oscillator on the circuit board according to one embodiment of the present invention. In FIG. 4A, the same numeral references are applied to the same constitutional elements as those in FIGS. 2A to 2C, and no same explanation is repeated.

The surface-mount temperature-compensated crystal oscillator is provided with: a crystal oscillator having a crystal unit, an oscillation circuit, and a voltage variable capacitive element; and temperature compensating mechanism 2 having a compensating voltage generation circuit and a low-pass filter. Similarly to the above-mentioned conventional crystal oscillator, at least the temperature compensating mechanism except capacitor C in the low-pass filter and the oscillation circuit including the voltage variable capacitive element are integrated in IC chip 11. IC chip 11 and quartz crystal blank 12 are hermetically sealed in container body 10 for surface-mounting with a recess by cover 13. Container body 10 is formed in a rectangular parallelepiped shape and is made of laminated ceramics. IC chip 11 is fixed to the inner bottom surface of the recess of container body 10. Crystal blank 12 in the recess is fixed to the step portion on the inner wall in the recess by conductive adhesive 14, as with the case shown in FIGS. 2A and 2B.

In this temperature-compensated crystal oscillator, capacitor C of low-pass filter 7 in temperature compensating mechanism 2 is fixed to the central area of the outer bottom surface of container body 10 as chip capacitor C′. Specifically, a pair of circuit terminals 16a, 16b is arranged in the central portion of the outer bottom surface of container body 10, and chip capacitor C′ is electrically and mechanically connected to the pair of circuit terminals 16a, 16b by solder or the like.

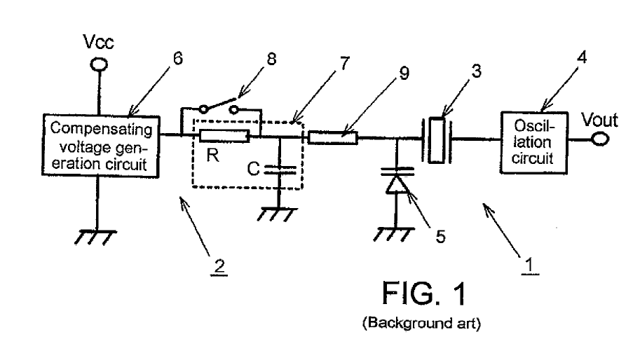

The inner bottom surface of container body 10 is provided with conductive path 17a connected to the ground terminal of IC chip 11 and conductive path 17b connected to a terminal of IC chip 11, the terminal of IC chip 11 connected to the junction between resistor R and high frequency blocking resistor 9 in low-pass filter 7. Circuit terminals 16a, 16b are electrically connected to conductive paths 17a, 17b, respectively, by via-holes (electrode through-holes) while air-tightness of container body 10 is maintained. The via-holes are routed through the laminated surface of the bottom wall of the laminated structure of container body 10 and formed in steps. Additionally, at four corners on the outer bottom surface of container body 10, similarly to those in shown in FIG. 1, mounting terminals 15 are formed. Conductive path 17a is also electrically connected to the mounting terminal, which is the ground terminal (GND), out of these mounting terminals 15.

The circuit board (i.e., wiring board) 18 is used to mount various electronic parts thereon in the device or apparatus provided with this surface mount temperature-compensated oscillator and is, for example, a glass epoxy printed-circuit board of a multilayered structure or a ceramic circuit board of a multilayered structure. In the mounting position of the surface-mount temperature-compensated crystal oscillator, opening 19 is formed from the mounting surface side. Opening 19 may be arranged as a hole that passes through circuit board 18 or may be arranged as a concave portion of circuit board 18. In this description, opening 19 is formed as the concave portion, and therefore opening 19 is provided with a bottom. Specifically, such a circuit board is formed by previously forming a through hole in other substrate layers except the lowermost substrate layer and then integrally laminating these substrate layers.

The surface-mount temperature-compensated crystal oscillator that is provided with chip capacitor C′ on the external bottom is surface-mounted on circuit board 18 by connecting each mount terminal 15 of the temperature-compensated crystal oscillator to connection terminal 30 arranged on the surface of circuit board 18 by solder or the like in a manner that chip capacitor C′ is accommodated in opening 19. In this case, assuming that opening 19 corresponds to chip capacitor C′, connection terminal 30 on circuit board 18 is formed in the position corresponding to mount terminal 15. Connection terminal 30 is electrically connected to other electronic parts mounted on circuit board 18 through conductive patterns (not shown) formed on or in circuit board 18.

With this mounting structure, even if the surface-mount temperature-compensated oscillator is reduced in size, chip capacitor C′ is attached to the outer bottom surface of container body 10 to configure low-pass filter 7. Therefore, the noise component in the temperature compensating voltage fed from the temperature compensating mechanism can be reduced and the phase noise of the temperature-compensated crystal oscillator can be reduced. Also, in order to suit the time constant of the low-pass filter to the use environment or the like, after assembling the temperature-compensated oscillator in which IC chip 11 and crystal blank 12 are accommodated and cover 13 is put, chip capacitor C′ of a suitable value can be selected.

Particularly, according to the mounting structure of this embodiment, since a large-capacitance capacitor can be selected as capacitor C that is a discrete part, the time constant of low-pass filter 7 is made larger and cut-off frequency fα is made smaller to suppress the high frequency component (i.e., noise component) sufficiently. Also, since chip capacitor C′ is accommodated in opening 19 in circuit board 18, the substantial height from the surface of circuit board 18 in the temperature-compensated crystal oscillator can be reduced, and thus substantial size reduction of the temperature-compensated oscillator is promoted.

When opening 19 is formed while the lowermost layer is remained in circuit board 18, which is a multilayered substrate, like this embodiment, there is no case to substantially reduce the area of the rear surface of circuit board 18, i.e., the surface on the side where the temperature-compensated crystal oscillator is not mounted. In other words, on the rear surface side of circuit board 18, other parts may be mounted or circuit patterns may be formed in the position corresponding to the opening. According to this embodiment, the area that is used to mount parts and to form circuit patterns on circuit board 18 can be maintained as before, it is possible to increase the packing density of electronic parts for circuit board 18, including circuit patterns.

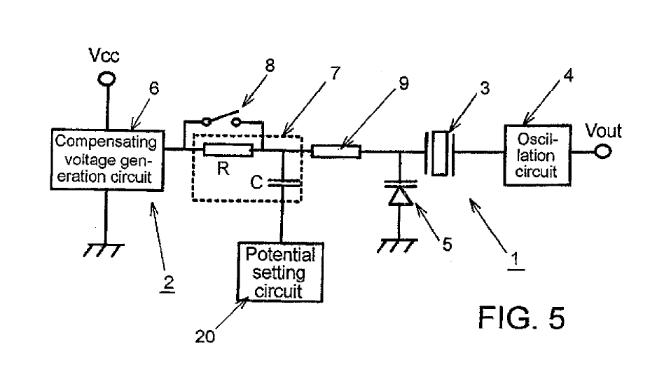

In the above-mentioned surface-mount temperature-compensated crystal oscillator, one end of capacitor C in low-pass filter 7 is connected to the ground potential. However, for example, as shown in FIG. 5, one end of capacitor C may be connected to potential setting circuit 20 that sets the potentials at both ends of capacitor C to the same potential when the ambient temperature is a reference temperature. Such a potential setting circuit is disclosed, for example, in JP, 2001-044758A. Potential setting circuit 20 is arranged in the temperature compensating mechanism in IC chip 11. In this way, when potential setting circuit 20 is arranged and one end of capacitor C is connected to potential setting circuit 20, a delay caused by the time constant by the capacitance itself can be prevented when the time-compensated crystal oscillator starts up.

In the above-mentioned explanations, chip capacitor C′ arranged on the outer bottom surface of container body 10 is capacitance C of low-pass filter 7 in the temperature compensating mechanism, however, there is no limitation on elements or parts arranged on the outer bottom surface of the container body. For example, a bias capacitor connected between the power source terminal and the ground terminal or a coupling capacitor arranged between the oscillation output terminal of IC chip 11 and output terminal (OUT) out of mounting terminals 15 may be arranged on the outer bottom surface of the container body. Further, the number of chip capacitor C′ arranged on the outer bottom surface of the container body is not limited to one, however, a plurality of chip capacitors may be arranged, for example, as a capacitor for a low-pass filter and a bypass capacitor.

The mounting structure and mounting method of the present invention may be applied to surface-mount crystal oscillator in addition to the surface-mount temperature-compensated crystal oscillator.

What is claimed is:

1. A structure in which a surface-mount crystal oscillator comprising a container body, a mounting terminal arranged on an outer bottom surface of said container body, a crystal blank hermetically sealed in said container body, and an IC chip having an oscillation circuit electrically connected to said crystal blank and hermetically sealed in said container body is mounted on a circuit board,
wherein a discrete part electrically connected to the IC chip is arranged on the outer bottom surface of said container body, said circuit board is provided with a connection terminal corresponding to said mounting terminal and an opening corresponding to said discrete part, said mounting terminal and said connection terminal are electrically and mechanically connected in a manner that said discrete part is accommodated in said opening, whereby said surface-mount crystal oscillator is surface-mounted on said circuit board.

2. The structure according to claim 1, wherein said discrete part is a chip capacitor.

3. The structure according to claim 2, further comprising a temperature compensating mechanism for performing temperature compensation for an oscillation frequency of the surface-mount crystal oscillator, wherein said discrete part is a capacitor in a low-pass filter included in said temperature compensating mechanism.

4. The structure according to claim 1, wherein the outer bottom surface of said container body is formed in an approximate rectangle, said mounting terminal is formed at a corner of said outer bottom surface and said discrete part is attached to a central portion of said outer bottom surface.

5. The structure according to claim 1, wherein said connection terminal and said mounting terminal are connected by solder.

6. The structure according to claim 1, wherein said opening is formed as a concave portion having a bottom.

7. The structure according to claim 1, wherein four pieces of said mounting terminals are provided and said four mounting terminals are arranged at four corners of said outer bottom surface, respectively.

8. A method of mounting a surface-mount crystal oscillator on a circuit board, said surface-mount crystal oscillator comprising a container body, a mounting terminal arranged on an outer bottom surface of said container body, a crystal blank hermetically sealed in said container body, and an IC chip having an oscillation circuit electrically connected to said crystal blank and hermetically sealed in said container body, said method comprising the steps of:
preparing said surface-mount crystal oscillator in which a discrete part electrically connected to the IC chip is arranged on the outer bottom surface of said container body; and
electrically and mechanically connecting said mounting terminal and a connection terminal, which is provided on said circuit board, in a manner that said discrete part is accommodated in an opening provided in said circuit board, whereby said surface-mount crystal oscillator is surface-mounted on said circuit board.

9. The method according to claim 8, wherein said surface-mount crystal oscillator comprises a temperature compensating mechanism for performing temperature compensation for an oscillation frequency of the surface-mount crystal oscillator, and wherein said discrete part is a capacitor in a low-pass filter included in said temperature compensating mechanism.

10. The method according to claim 8, wherein said opening is formed as a concave portion having a bottom.
